(19) United States
(12) Patent Application Publication
(10) Pub. No.: US 2025/0323009 A1
(43) Pub. Date: Oct. 16, 2025

(54) SYSTEMS AND METHODS FOR TEMPERATURE CONTROL IN ELECTRON MICROSCOPY

(71) Applicant: Protochips, Inc., Morrisville, NC (US)

(72) Inventors: John Damiano, JR., Holly Springs, NC (US); David P. Nackashi, Raleigh, NC (US); Franklin Stampley Walden, II, Raleigh, NC (US); Patrick Wellborn, Durham, NC (US); William Bradford Carpenter, Asheville, NC (US); Nelson L. Marthe, JR., Cary, NC (US); Daniel Stephen Gardiner, Wake Forest, NC (US); Katherine Marusak Stephens, Garner, NC (US); William Ivan Lisenby, Wendell, NC (US)

(21) Appl. No.: 19/176,335

(22) Filed: Apr. 11, 2025

Related U.S. Application Data
(60) Provisional application No. 63/632,852, filed on Apr. 11, 2024.

(51) Int. Cl. H01J 37/20; G01N 1/42; G01N 1/44

(52) U.S. Cl. CPC H01J 37/20; G01N 1/42; G01N 1/44; H01J 2237/2065

(57) ABSTRACT

A heating and cooling system for in-situ electron microscopy capable of independent temperature control of a MEMS sample support coupled to the control of a thermoelectric device is disclosed. The thermoelectric device heats and cools components of the in-situ electron microscopy system while a heating element on the MEMS sample support precisely controls the sample temperature.

### CROSS-REFERENCE TO RELATED APPLICATION

This application claims priority to U.S. Provisional Patent Application No. 63/632,852, filed on Apr. 11, 2024, the entire contents of which is hereby incorporated by reference in its entirety.

### TECHNICAL FIELD

The disclosure relates generally to temperature control of samples in in-situ electron microscopy. In particular, this disclosure relates to a combined heating and cooling system for changing the temperature of an in-situ electron microscopy sample above and below room temperature.

### BACKGROUND

The kinetics of electrochemical reactions are often dictated by temperature. There is a need to observe and analyze these electrochemical reactions both above and below room temperature at a resolution attainable only in an electron microscope environment. To properly observe and analyze these electrochemical reactions in an electron microscope environment, a transmission electron microscopy (TEM) sample holder that can precisely heat and cool samples over a wide range of temperatures is required. Additionally, the TEM sample holder must be operable to apply an electrical bias to electrodes in solution while generating minimal thermal drift to support acquisition of high-resolution images and analytical data.

Current TEM holders for cooling samples are used for Cryogenic Electron Microscopy (cryo-EM). These cryo-EM sample holders utilize liquid nitrogen to preserve biological specimens by embedding them in an environment of vitreous ice at a fixed temperature of approximately −170° C. Other applications for cryo-EM include electrical biasing of samples on a silicon chip patterned with electrodes to study quantum materials, superconductors, and batteries.

An alternative approach to TEM sample cooling includes the use of thermoelectric systems and devices. Existing thermoelectric systems and devices are not able to reach liquid nitrogen temperatures. However, rather than providing a fixed low temperature like cryo-EM, thermoelectric cooling can control sample temperature through programmable setpoints. Advantageously, this results in predictable and directional thermal expansion without the vibrations that arise from boiling liquid nitrogen. Further, programmable setpoints improve the accuracy and minimize sample drift in the electron microscope environment, thereby improving image quality. Yet another advantage of thermoelectric cooling is providing an indefinite period of imaging once an electron microscope environment is cooled. This avoids the need to replenish liquid nitrogen (and the vibrations introduced each time this occurs) as required in traditional cryo-EM systems. The advantages of thermoelectric cooling in electron microscopy are further detailed in WIPO 2023/009550 A1, which is herein incorporated by reference in its entirety.

Preferably, during observation and analysis of a sample in in-situ electron microscopy, the temperature is confined, measured, and controlled as close to the sample area as possible. Existing in-situ heating systems can heat the sample area with a low power, micro-heating micro-electro-mechanical systems (MEMS) sample support, but these systems cannot cool below room temperature and do not offer sufficient control for monitoring and controlling the local sample temperature. Additionally, thermoelectric cooling cannot easily be localized to the sample observation area partially due to the size, materials, and power constraints of a thermoelectric device.

MEMS sample supports are conducive for in-situ electron microscopy with liquid samples. These MEMS devices include features supporting electrochemistry experiments as well as sample heating capabilities. An example of heating capability is Joule heating by forcing current through a metal heating element located on the silicon frame of the chip, as described in U.S. Pat. No. 10,128,079, which is herein incorporated by reference in its entirety.

A challenge for both heating and cooling for electron microscope holders is thermal drift resulting from thermal expansion of materials. Thermal drift is disadvantageous because electron microscopy is typically performed at magnifications with a field of view often less than one square micrometer, and any movements caused by thermal drift severely limit the ability to focus on and view a sample of interest over time.

Yet another problem with current in-situ microscopy systems and devices is that heating and electrochemistry cannot easily be combined onto one device without compromising performance. This is partially due to the relatively high amount of electrical voltage and current used in the circuit to heat the device. The electrical voltage and current applied to the heating circuit results in current leakage to and electromagnetic interference (EMI) with the electrochemistry circuit. The electrochemistry experiments produce low-level electrical signals in the pico-amp range, and the EMI/leakage from the heating circuit creates electrical noise on the electrochemistry circuit, overwhelming the electrochemistry signals.

Thus, there is a need for a TEM sample holder capable of independent control of a MEMS sample support coupled to the control of a thermoelectric device for the purpose of in-situ electron microscopy. There is a further need for a TEM sampler holder control system that minimizes noise coupling and enables liquid heating while performing electrochemistry experiments without problematic interference with the electrochemistry measurements.

### SUMMARY

This summary is provided to introduce a selection of concepts in a simplified form that are further described below in the detailed description. This summary is not intended to identify key features or essential features of the claimed subject matter, nor is it intended to be used to limit the scope of the claimed subject matter.

The present disclosure generally relates to a heating and cooling system for in-situ electron microscopy operable for independent temperature control of a MEMS sample support coupled to the control of a thermoelectric device. The thermoelectric device heats and cools components of the microscopy system while a heating element on the MEMS sample support precisely controls the sample temperature. The heating and cooling system provides a platform for in-situ thermal studies of a variety of materials, including samples in liquid and electrochemistry. The heating and cooling system is compatible with the imaging and analytical functionalities of electron microscopes when integrated with a sample holder for microscopy environments including, but not limited to, a scanning electron microscope (SEM), TEM, scanning transmission electron microscopy (STEM), electron energy loss spectroscopy (EELS), and energy-dispersive x-ray spectroscopy (EDS/EDX). The heating and cooling system can also be used with other types of microscopy, including X-ray microscopy, scanning probe microscopy, and optical microscopy. Controls are provided to confine, measure, and control the temperature close to the sample area by coupling a thermoelectric device to a MEMS sample support to monitor and control the sample temperature.

A control system is disclosed that enables accurate, stable measurements by heating to temperatures higher than room temperature as well as cooling to temperatures lower than room temperature. In some embodiments, a holder system that minimizes the effects of thermal expansion on sample imaging through a combination of thermal efficiency, material selection, and assembly construction is disclosed. The control system minimizes noise coupling, enabling liquid heating while performing electrochemistry experiments without problematic voltage shifts in the electrochemistry measurements. Additionally, in at least one aspect, the present disclosure includes a sample holder system that minimizes the effects of thermal expansion on sample imaging through a combination of thermal efficiency, material selection and assembly construction.

### BRIEF DESCRIPTION OF THE DRAWINGS

The present embodiments are illustrated by way of example and are not intended to be limited by the figures of the accompanying drawings.

FIG. 1 depicts a side view of a heating and cooling TEM holder according to an embodiment of the present disclosure.

FIG. 2 depicts a side view of the TEM holder shown in FIG. 1, with some outer portions removed for visibility of some of the internal components.

FIG. 3 depicts an exploded view of a portion of the TEM holder shown in FIGS. 1-2.

FIG. 4 depicts a temperature drift graph corresponding to a heating and cooling TEM holder according to one embodiment of the present disclosure.

FIG. 5 illustrates an exploded view of a closed cell holder according to one embodiment of the present disclosure.

FIG. 6 illustrates a perspective view of a closed cell holder according to one embodiment of the present disclosure.

FIG. 7 illustrates a top perspective view of a closed-cell holder according to one embodiment of the present disclosure.

FIG. 8 illustrates a top perspective view of a closed-cell holder according to one embodiment of the present disclosure.

FIG. 9 illustrates a top perspective view of a closed-cell holder according to one embodiment of the present disclosure.

FIG. 10 illustrates a top perspective view of a closed-cell holder according to one embodiment of the present disclosure.

FIG. 11 illustrates a MEMS device according to one embodiment of the present disclosure.

FIG. 12 depicts a control system for a Peltier, chip coil heater, and coil measurement according to one embodiment of the present disclosure.

FIG. 13 depicts a graphical representation of the temperature of components of a heating and cooling TEM holder according to one embodiment of the present disclosure.

FIG. 14 depicts a graphical representation of the temperature and sample drift of a heating and cooling TEM holder according to one embodiment of the present disclosure.

FIG. 15 illustrates a screenshot of a software platform for managing thermal control of a TEM holder according to one embodiment of the present disclosure.

FIG. 15A illustrates a screenshot of a software platform for managing thermal control of a TEM holder according to one embodiment of the present disclosure.

FIG. 15B illustrates a screenshot of a software platform for managing thermal control of a TEM holder according to one embodiment of the present disclosure.

FIG. 15C illustrates a screenshot of a software platform for managing thermal control of a TEM holder according to one embodiment of the present disclosure.

FIG. 16 illustrates a screenshot of a software platform for managing thermal control of a TEM holder according to one embodiment of the present disclosure.

FIG. 17 illustrates a screenshot of a software platform for managing thermal control of a TEM holder according to one embodiment of the present disclosure.

FIG. 18 illustrates a graphical representation of interference between a heating circuit and an electrochemistry circuit.

FIG. 19 illustrates a graphical representation of interference between a heating circuit and an electrochemistry circuit.

### DETAILED DESCRIPTION

The following description and figures are illustrative and are not to be construed as limiting. Numerous specific details are described to provide a thorough understanding of the disclosure. In certain instances, however, well-known or conventional details are not described in order to avoid obscuring the description. References to “one embodiment” or “an embodiment” in the present disclosure may be (but are not necessarily) references to the same embodiment, and such references mean at least one of the embodiments.

In at least one aspect of the present disclosure, a temperature control system and a heating and cooling system for heating and cooling a sample in in-situ electron microscopy is disclosed. The temperature control system described herein supports imaging and analytical capabilities of electron microscopy systems including, but not limited to, SEM, TEM, STEM, EELS, EDS/EDX, X-Ray microscopy, scanning probe microscopy, and optical microscopy. The temperature control system controls the temperature of a MEMS sample support connected to (e.g., coupled to) a thermoelectric device designed to heat and/or cool the heating and cooling system.

The MEMS sample support includes a heating element for controlling the temperature of a sample for the in-situ electron microscopy. For example, the MEMS sample support includes at least one heat source element, an insulating material or component (e.g., thin dielectric), and a thermally conductive structural frame. The heat source element is electrically insulated from the thermally conductive structural frame via the thin dielectric. The MEMS sample support further includes a dielectric covering that protects the heat source element from environmental conditions. In at least one aspect of the present disclosure, the MEMS sample support includes a first dielectric including a thickness between about 100 nm and about 500 nm and a second dielectric including a thickness between about 1 μm and about 5 μm. The first dielectric can be used between two MEMS sample supports to control an exposed electrode area. The second dielectric can cover coils of the heat source elements of the MEMS sample supports to improve the resiliency to dielectric breakdown and to mechanically protect from abrasion on the gasket that occurs when expanding/contracting during heating/cooling.

In some embodiments, additional measurement devices are added to monitor the temperature of the components in the in-situ microscopy system. The in-situ microscopy system components include, but are not limited to, the two sides of the thermoelectric device, parts used to couple the thermoelectric device to the MEMS sample support, microscope touch points, or parts needed to cool the hot side of the thermoelectric device. These additional measurement devices provide protective feedback for the control system to cut or reduce power to the thermoelectric device or the MEMS sample support. These measurement devices include, but are not limited to, resistance temperature detectors (RTDs), LM335, thermistors, thermocouples or other commonly used measurement devices wired to a control system. The measurements sensors are monitored via software (e.g., software platform), which includes software settings that establish the acceptable temperature range for a given part of the system and can also be used as feedback in additional control for either the thermoelectric device or the MEMS sample support.

The MEMS sample support is operable for in-situ thermal analysis of materials (e.g., liquid samples and electrochemistry). The MEMS sample support is operable for SEM, TEM, STEM, EELS, EDS/EDX, x-ray microscopy, scanning probe microscopy, and optical microscopy.

The thermoelectric device may be used to control the direction of current. As a result of the direction of current, heat transfers from one side of the thermoelectric device to another side. Reversing the current flow will cause heat to transfer in the opposite direction. As one example, the thermoelectric device includes a Peltier device. In some embodiments, the present invention is operable to remove mechanical vibrations from a sample observation region and contained in a body of a sample holder, away from a sample of interest.

In some embodiments, the sample holder is thermally coupled to the MEMS sample support. The thermal coupling includes high thermal conductivity material with low coefficients of thermal expansion (“CTE”). For example, and without limitation, copper has a CTE of approximately 16 ppm/K and a thermal conductivity of approximately 398 W/mK. Tungsten-copper (WCu) has a CTE of approximately 7 ppm/K and a thermal conductivity of approximately 200 W/mk. Polyether ether ketone (PEEK) has a CTE of approximately 60 ppm/K and a thermal conductivity of approximately 0.45 W/mK. Titanium has a CTE of approximately 9.5 ppm/K and a thermal conductivity of approximately 11.4 W/mK. Thermal conductivity of a material is a measure of its ability to conduct heat. Heat transfer occurs at a lower rate in materials of low thermal conductivity than in materials of high thermal conductivity. For example, metals typically have high thermal conductivity and are very efficient at conducting heat. The coefficient of thermal expansion describes how the size of an object changes with a change in temperature. Specifically, the coefficient of thermal expansion measures the fractional change in size per degree change in temperature at a constant pressure, such that lower coefficients describe lower propensity for change in size. In some embodiments, to minimize heat loss to a microscope goniometer, the sample holder system includes a vacuum rated plastic and/or rubber. In some embodiments, a vacuum source (e.g., column vacuum) of the electron microscope can evacuate an inside of a sample holder and reduce convective heat loss to touch points of a microscope and ambient air, thereby improving heat transfer efficiency between the thermoelectric device and the MEMS sample support. In some embodiments, a flexible coupling may be used to connect the thermoelectric device and the MEMS sample support.

In some embodiments, the system described herein is designed to measure a change in resistance of one or more circuits and/or electrical sense elements at a fixed current. Based on the change in resistance of the one or more circuits or electrical sense elements and the temperature coefficient of resistance (TCR), the system is further operable to determine a corresponding temperature.

In some embodiments, the MEMS sample support comprises at least one heating element electrically insulated from the thermally conductive structural frame by a thin dielectric and electrically insulated from environmental conditions exposed to the device by a dielectric covering the heat source element. The at least one heat source element is arranged so that thermal energy can be efficiently conducted into the thermally conductive structural support frame and then further conducted in a stable and uniform manner to the at least one observation region which is a thin continuous membrane.

In various embodiments, the heating element may be in the observation region or patterned on a robust MEMS substrate. The heating element on the MEMS substrate may be isolated by at least one film to allow the heating element to accurately heat the sample or fluid while being responsive to system temperature. The MEMS heating device can be inserted into a microscope sample holder that supports a variety of imaging and analytical techniques, e.g., SEM, TEM, STEM, X-ray synchrotron, scanning probe microscopy, and optical microscopy.

The connection between the thermoelectric device and the MEMS sample support must provide efficient thermal coupling. To minimize thermal drift and time-to-equilibrium, the connection between the thermoelectric device and the MEMS sample support is made from materials with high thermal conductivity and low coefficients of thermal expansion. Further, there is sufficient thermal contact between one side of the thermoelectric device and the MEMS sample support.

In some embodiments, to minimize heat loss to a microscope goniometer, parts with lower thermal conductivity, such as many vacuum-rated plastics or rubbers, may be employed as a thermal break between the hot or cold parts of the sample holder and the components in direct contact with the microscope (“touch points”) or outside ambient air.

The column vacuum of the electron microscope or another vacuum source may be used to evacuate the inside of the sample holder and reduce convective heat loss to the microscope components and ambient air, improving the efficiency of the heat transfer between the thermoelectric device and the MEMS sample support.

The heating and cooling system described herein includes flexible members connecting the thermoelectric device and the MEMS sample support to counteract compressive and tensile stresses that form as materials warm and cool. The flexible members absorb these stresses and allow materials to naturally expand and contract with the MEMS sample support and the thermoelectric device.

The heating and cooling system described herein can be used to heat and cool components with a thermoelectric device and use circuits patterned on MEMS sample support to measure the temperature at the sample location. For example, the temperature on the MEMS sample support is monitored based on the change in resistance of one or more circuits, or electrical sense elements, at a fixed current. Since the resistance of these elements can be used to determine temperature through their temperature coefficient of resistance (TCR), these measurements may be used as feedback in a closed-loop system or in an open-loop system with control of current or voltage in the thermoelectric device or from pre-established calibrations.

In at least one aspect of the present disclosure, a heating element including a sensor is positioned at a tip of the sample holder. For example, and without limitation, a nichrome wire or cartridge heater including a RTD may be positioned on the lid or in the tip of the sample holder in proximity to the sample support. In at least one aspect of the present disclosure, the heating element (e.g., wire or cartridge heater) is not positioned on the MEMS sample support.

In some embodiments, the thermoelectric device is driven by controlling the current through the thermoelectric device to specific temperatures or target power at programmable ramp rates. The thermoelectric device may be set either at, slightly below, or slightly above the target temperature for an in-situ environment. The thermoelectric device can be changed at controlled rates to minimize thermal drift or speed up the cooling or heating process with precise control of power and heat in the system. However, because the thermoelectric device is not directly at the sample observation region, there is a time delay, with changes in temperature at the sample being observed later than when power is applied to the thermoelectric device.

The heat from the thermoelectric device can be directed to and from components surrounding the MEMS sample support, depending on the materials and construction of the sample holder or by physically moving parts of the system to form thermal connections. Additionally, the heating element on the MEMS sample support can be independently controlled via Joule heating to precisely change the temperature at the sample. The heating element on the MEMS sample support may include a temperature sensing element that is operable to determine a temperature based on a change in resistance. Alternatively, the heating element and the temperature sensing element may be on separate circuits on the MEMS sample support.

In some embodiments, the thermoelectric device includes cooling components contacting the thermally conductive MEMS sample support. This enables a power reduction of the heating element on the MEMS sample support to cool the sample. To study transient effects that occur at a specific temperature or temperature range, like freezing of water, the thermoelectric device is driven to slightly below the target temperature. Concurrently, the MEMS sample support is driven to slightly above the target temperature. Once the in-situ microscopy system reaches thermal equilibrium and the thermal drift is reduced, the control system adjusts the power into the heating element on the MEMS sample support at a programmable rate to heat or cool the sample through this temperature range with minimal drift. The temperature control system is further operable to monitor and control the drift magnitude and drift rate because the change in temperature is relatively small and the rate of change is controlled. A lower drift rate is advantageous in that it enables imaging at higher magnifications and higher resolution.

In some embodiments, the control system is designed to control the heating of the sample to elevated temperatures through the heating element on the MEMS sample support. This increases the temperature of components surrounding and in contact with the MEMS sample support. The TEC can be used to counteract heat from the sample support and cool the surrounding components to reduce drift and widen the controllable temperature range applied at the sample. The power of the TEC can be adjusted dynamically by the user or an automated control system triggered as power is increased into the heating element on the MEMS sample support. Alternatively, the power into the TEC can be set based on changing temperature at the sample with prior knowledge of power required by the heating element on the MEMS sample support to reach the sample target temperature.

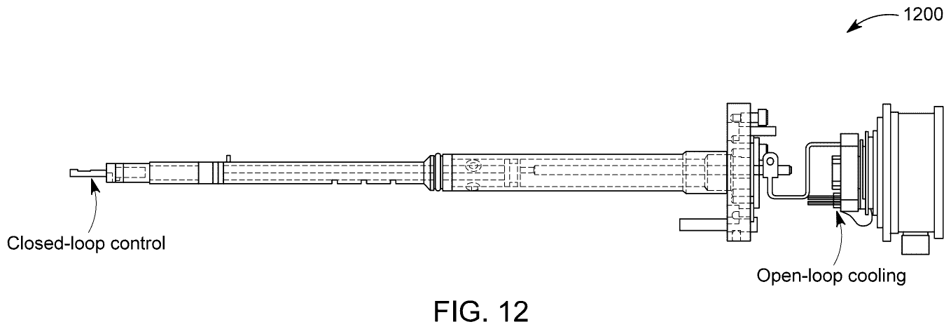

In some embodiments, the in-situ microscopy system is controlled based on a predetermined or expected temperature operating range. The lower temperature or power required to reach elevated temperatures is factored into a setpoint for the TEC. Based on the temperature or power required, the TEC is commanded to cool the system accordingly. For example, and without limitation, as shown in FIG. 12, the in-situ microscopy system includes an open-loop strategy to reduce changes in power in the Peltier during the experiment, with only enough power input into the system to meet the temperature operating range expected out of the heating element on the MEMS sample support. In at least one aspect of the present disclosure, the in-situ microscopy system includes a closed-loop controller utilizing one or more temperature sensors positioned on the cold-finger, the tip, or the MEMS sample support to provide feedback.

As used herein, “sample holder” refers to a component of an electron microscope providing the physical support for specimens under observation. Sample holders used for TEMs and STEMs include a rod that is comprised of an end, a barrel, and a sample tip. In addition to supporting the sample, the sample holder provides an interface between the inside of the instrument, typically at high vacuum, and the outside laboratory environment. To use the sample holder, at least one device is inserted into the sample tip. The sample holder is inserted into the electron microscope through a vacuum load-lock. During insertion, the sample holder is pushed into the electron microscope until the sample holder stops, which results in the sample tip of the sample holder being positioned in the column of the microscope between the upper and lower objective lens. In this position, the barrel of the sample holder bridges the space between the inside of the microscope and the outside of the vacuum load lock, and the end of the sample holder is outside the microscope. The exact shape and size of the sample holder varies with the type and manufacturer of the electron microscope. Sample holders for most SEMs as well as other microscopy instruments such as scanning probe microscopy, X-ray synchrotron, and light optical microscopy, correspond to a structure that fixtures a device and mates to a stage on the specified microscopy instrument. For each of these microscopy instruments, how the mount enters the inside of the microscope and how the mount is stabilized in the microscope can vary. The sample holder can also be used to provide stimulus to the specimen, and this stimulus may include temperature, electrical current, electrical voltage, mechanical strain, etc.

As used herein, “sense element” refers to a component used to measure current or voltage on a MEMS sample support device (e.g., temperature control device) and may be located on either the frame or membrane. Electrical contacts between the sample holder and the MEMS sample support device can be used in conjunction with sense elements. Electrical contacts are made by defined pad regions, and the pad regions are generally directly on the surface of the respective element and in a region over the frame. For example, and without limitation, these pad regions have areas of at least 100 microns. About 100 microns defined on the element either by (1) a patterned region of material where the pad material is different from the element material, or (2) a patterned region of the element where the pad region is comprised of the same material as the element material. In some embodiments, the use of another material is preferred when a low resistance and/or ohmic electrical contact cannot be achieved through a physical contact between the holder and the element material. If the element material is a metal such as tungsten, the pad region can be a large area within that element on the frame region. If the element material is a semiconductor or ceramic such as silicon carbide, a non-magnetic metal such as gold, tungsten, platinum, titanium, palladium or copper and non-magnetic alloys could be used. Multiple pads per element, and multiple elements per device can be used. In some embodiments, a secondary circuit or set of electrodes that can source and measure independently of the heating element circuit is used. Advantageously, this enables the present invention to support an electrochemistry or electro-thermal device that can make electrical measurements of the sample or fluid independent of the heating circuit.

The thermoelectric device described herein is a solid-state heat pump that operates when an electrical current flows through the device. The direction of current will cause heat to transfer from one side of the device to the other side of the device. Reversing the direction of the current will cause heat to transfer in the opposite direction. The TEC may be a Peltier element. While the TEC does not introduce mechanical vibrations that can affect imaging, the TEC size, materials, and power consumption requires the TEC to be removed from the sample observation region and contained in the body of the holder, relatively far from the sample of interest.

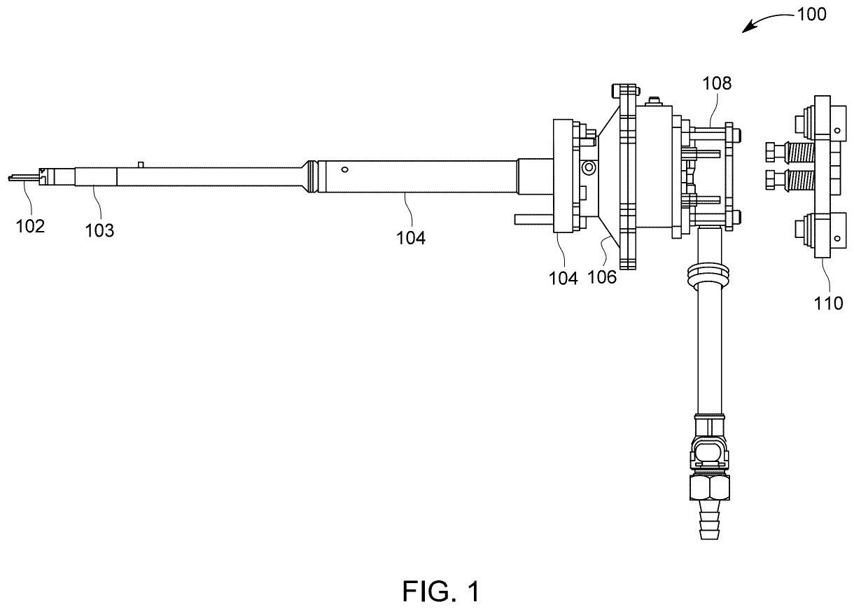

FIG. 1 depicts a side view of a heating and cooling TEM sample holder according to an embodiment of the present disclosure. As shown in FIG. 1, a TEM sample holder 100 is disclosed. As can be seen in the view shown in FIG. 1, the TEM sample holder 100 includes a tip 102, a thermal break 103, an external body 104 of the holder, a sealed housing 106, cooling components 108, and electrical connectors 110. Sealed Peltier housing 106 includes a Peltier element (not shown in this view). The cooling components 108 are positioned on the “hot side” of the sealed Peltier housing 106 (which includes the Peltier element) and provide active cooling to the hot side. In at least one embodiment, cooling components 108 include a water-cooled heat exchanger. In various other embodiments, cooling components 108 include cooling fins, a thermal battery, or a heat-sink to the TEM column. Thermal break 103 helps keep heat in the tip 102 and away from the touch points of the microscope. Electrical connectors 110 are used, for example, to power the Peltier device, measure the RTDs, and connect to the chip. In the most common configuration/use of the Peltier device, the cold side of the Peltier device is connected to the cold finger and ultimately the tip. The hot side of the Peltier device is connected to the cooling components (e.g., cooling block). This can be reversed, for example, when current is reversed through the Peltier device, such that the hot side is connected to the finger and the tip, and the cold side is connected to the cooling components.

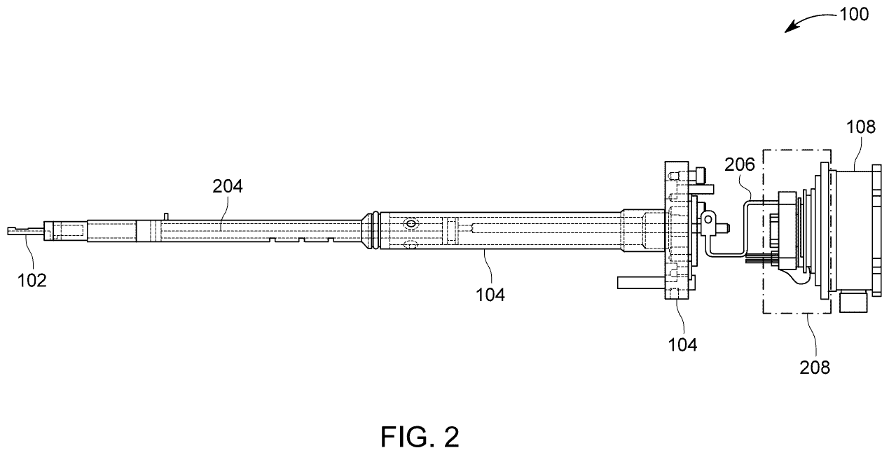

FIG. 2 depicts a side view of the TEM holder shown in FIG. 1, with some outer portions removed for visibility of some of the internal components. The TEM sample holder 100 includes tip 102, the external body 104 (which is shown as transparent in FIG. 2), a cold finger 204, which is the rod on the inside of the external body 104 shown as transparent, the flexible member 206, the Peltier assembly 208, and the cooling components on the hot-side of the Peltier assembly 208. The external body 104 provides microscope tough points and external vacuum sealing for the holder. Cold finger 204 runs longitudinally within external body 104 but does not touch external body 104. Cold finger 204 can be a device designed for maintaining a sample at a low temperature and/or generating a localized cold surface. The vacuum provided by the external body 104 helps insulate cold finger 204 from the external body 104 (as well as the other microscope touch points).

The cold finger can be positioned on an interior of a TEM holder. The cold finger may include a highly conductive material (e.g., oxygen-free copper). The cold finger can include a rod-like shape including a tapered body. The cold finger body narrows closer to the tip of the TEM holder to maximize conduction while limiting mass near the tip-end that would need to cool. For example, and without limitation, in at least one aspect of the present disclosure, a Peltier device can be positioned about 300 mm away from a tip of the TEM holder and the cold finger is configured to transmit heat quickly without adding unnecessary thermal load. The cold finger can include a flexible component positioned between the cold finger and the Peltier device to reduce stress on the TEM holder.

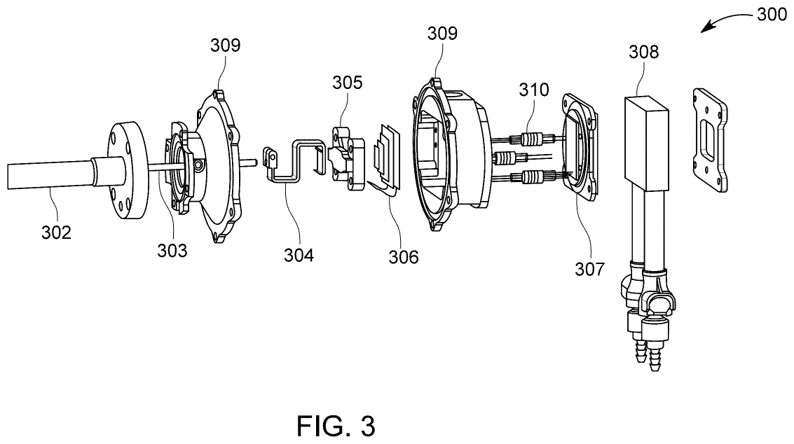

FIG. 3 depicts an exploded view of a portion of the TEM holder shown in FIGS. 1 and 2. The TEM sample holder 300 includes the external body of the holder 302, cold finger 303, flexible member 304, Peltier clamp 305, Peltier 306, Peltier heat-sink 307, cooling for the heat-sink 308, sealed Peltier housing 309, and resistance temperature detectors (RTDs) 310.

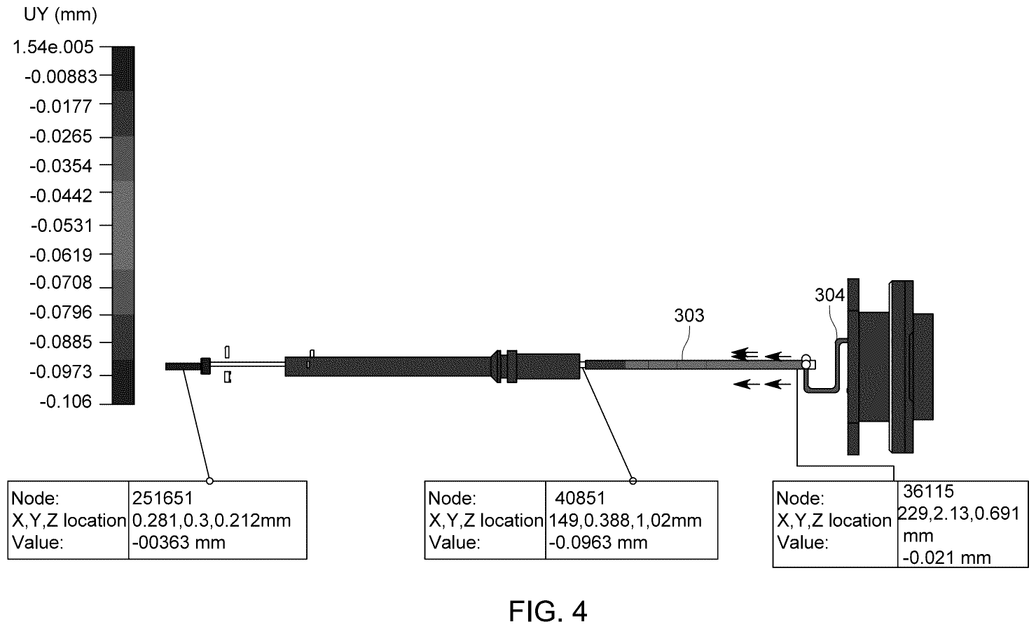

FIG. 4 illustrates the modeled contraction of the cold finger 303 as it gets cold, along with the temperature gradient along the cold finger 303. The horizontal arrows shown in FIG. 4 indicate the direction of contraction of the cold finger 303. The flexible member 304 absorbs a significant amount of the contraction because the tip is secured to the thermal break, and the Peltier and the hot side are fixed to the holder.

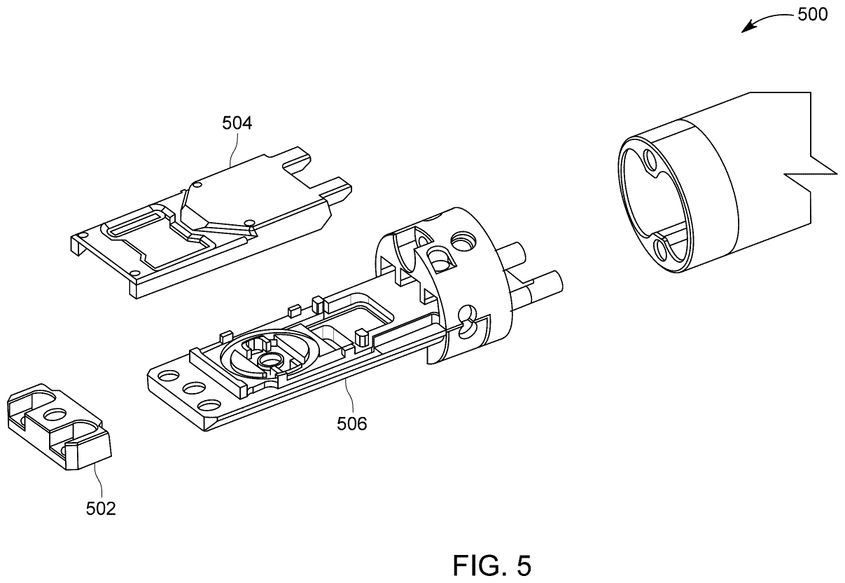

FIG. 5 illustrates a tip of a sample holder according to one embodiment of the present disclosure. The sample holder tip 500 includes a locking mechanism 502, a lid 504, and a cell holder 506. Cell holder 506 comprises a titanium portion with the wetted parts of tip, and a tungsten-copper (WCu) portion in thermal contact with lid 504 and the cold finger (not shown here). The thermal break is not explicitly shown in FIG. 5; however, it may be included in various embodiments. For example, and without limitation, the locking mechanism includes a plurality of holes for receiving a plurality of fasteners (e.g., screws).

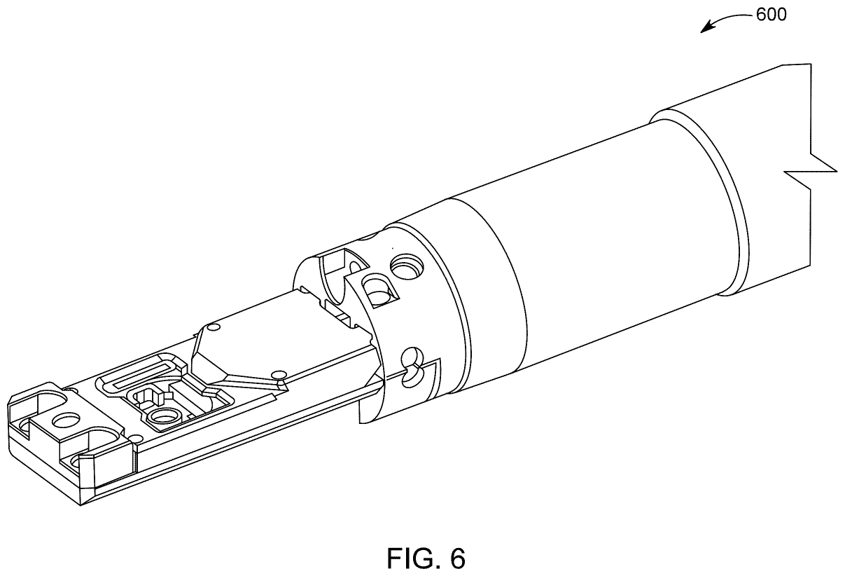

FIG. 6 illustrates an assembled version of a tip of a sample holder as shown in FIG. 5. In the embodiment shown in FIG. 6, the cell holder 600 locks or snaps together; however, in other embodiments, the cover may be screwed into the tip at the front and the back, or otherwise fastened to the tip.

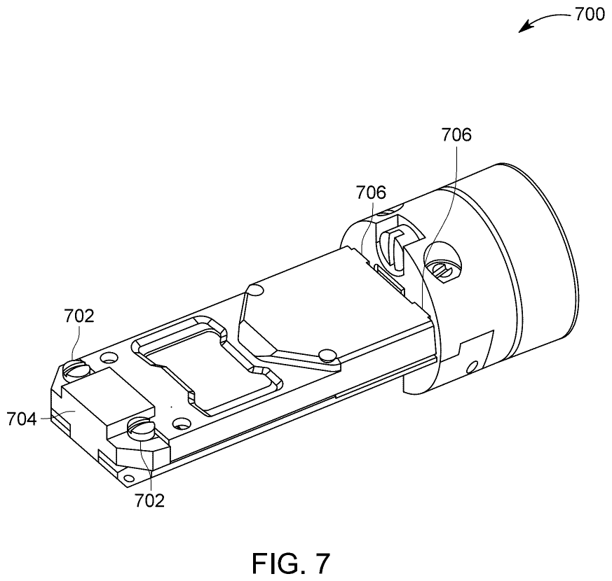

FIGS. 7-10 depict various embodiments for sealing the closed-cell holder in accordance with the disclosure described herein. The seal of the closed-cell holder facilitates good heat transfer and can be disassembled/reassembled without completely removing any of the small screws. Advantageously, this makes it easier to load in a glovebox, because it can be difficult to locate and manipulate small screws.

FIG. 7 illustrates a top perspective view of an embodiment of the closed-cell holder. The two front screws 702 are loosened but not removed. Once screws 702 are loosened, then blocking plate 704 can be slid backwards, enabling the lid to be removed about fastener points 706.

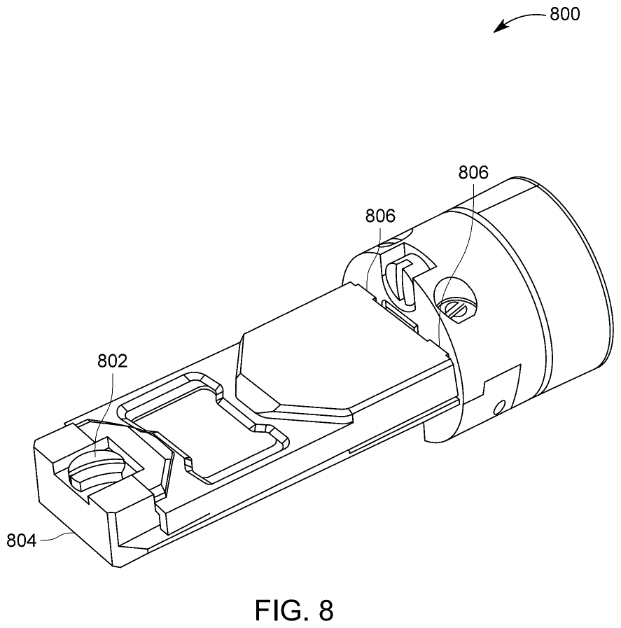

FIG. 8 illustrates a top perspective view of an embodiment of the closed-cell holder. Screw 802 in fastener block 804 acts as a cam to fasten the lid in place. The lid rotates/opens about fastener points 806.

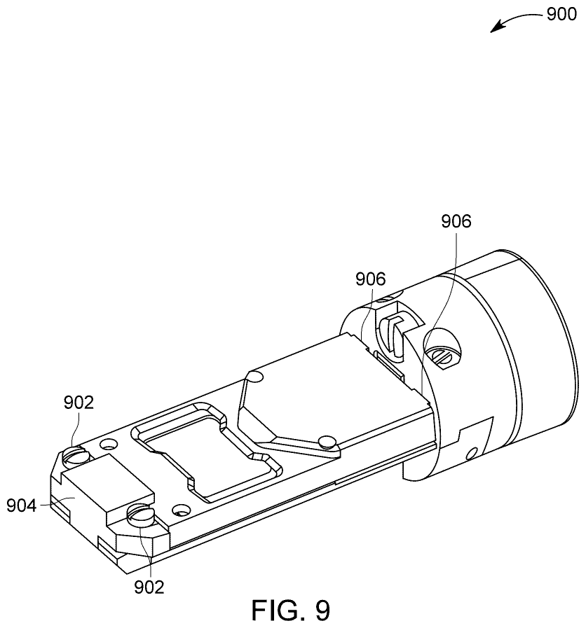

FIG. 9 illustrates a top perspective view of a preferred embodiment of the closed-cell holder. The two front screws 902 are loosened but not removed. Once the screws 902 are loosened, then blocking plate 904 can be slid backwards, enabling the lid to be removed about fastener points 906.

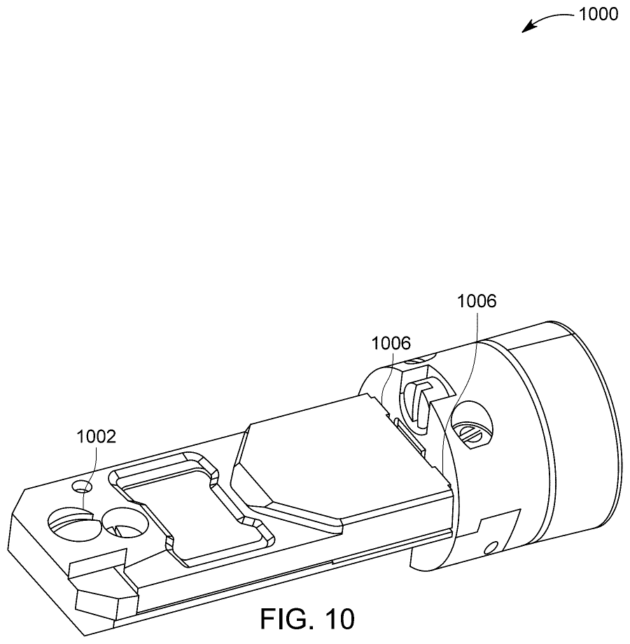

FIG. 10 illustrates a top perspective view of an embodiment of the closed-cell holder. The screw 1002 is loosened slightly, then the lid slides back and can be removed.

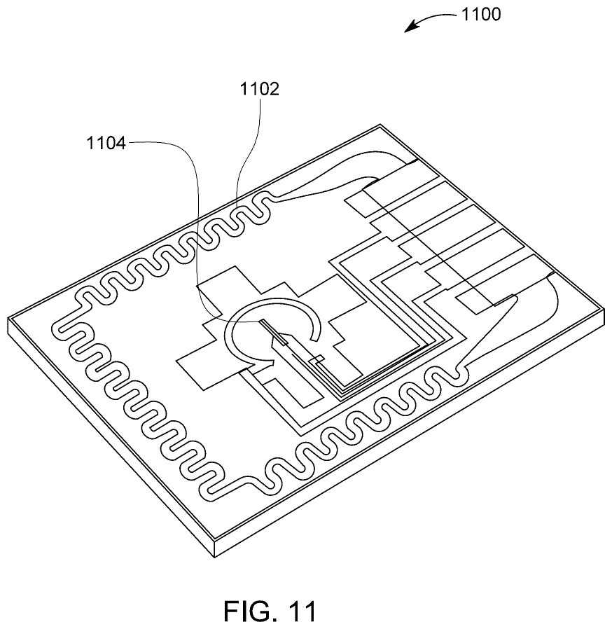

FIG. 11 depicts a MEMS device 1100 including a frame heater 1102 and a plurality of electrodes 1104 according to one embodiment of the present disclosure. The plurality of electrodes 1104 comprises an array of probes in a fixture providing a high resistance between leads that translate into leakage current of sub-nA at 10V. The electrodes are electrochemistry electrodes, usually a working electrode, reference electrode, and counter electrode. The reference electrode and counter electrode may be combined into a single electrode for whole-cell measurements. Each electrode has a controlled wetted area and controlled materials depending on the particular application. The MEMS device can include insulated (e.g., dielectric layer) traces leading to the electrode from liquid in the cell. In at least one aspect of the present disclosure, the working electrode is designed to only be wet over a visible window to enable visualization of an entire reaction occurring on the working electrode. In at least one aspect of the present disclosure, the working electrode includes platinum and/or glassy carbon. In at least one aspect of the present disclosure, the counter electrode is symmetrically shaped around the working electrode. The counter electrode may include an inert material (e.g., platinum) and include a larger surface area relative to the working electrode.

FIG. 12 depicts a control system for a Peltier, chip coil heater, and coil measurement according to an embodiment of the present disclosure. In another embodiment, the section labeled “Open-loop cooling” may be either open-loop or closed-loop. Open-loop cooling is preferred to avoid current changes on the large powered device during experiments except for exactly when a change of the setpoint is desired. The current may be reversed through the Peltier and warm components in the system.

Closed-loop cooling is preferred on MEMS environmental chip (E-chip), but this could be a fixed current to measure temperature changes. The MEMS E-chip includes a patterned metal heater on an environmental chip. In an embodiment, the heater may be ceramic instead of metal. The heater (whether ceramic or metal) may be on the frame or the window.

Conversely, the current direction through the thermoelectric device can be reversed to warm components in the in-situ microscopy system. At the end of an experiment, the internal components can be warmed to return to room temperature before removal from vacuum. Advantageously, this prevents corrosion or other damage due to condensation.

In at least one aspect of the present disclosure, the control system is configured to set the in-situ microscopy system to thermal equilibrium. This can include setting a sample temperature to at or near room temperature and/or setting a Peltier RTD to at or near room temperature. The control system can further monitor power to a MEMS sample support and/or the Peltier to determine when thermal equilibrium is achieved.

In at least one aspect of the present disclosure, the control system is configured for emergency operations. For example, and without limitation, the emergency operations include an emergency stop. The control system can quickly ramp current down on the MEMS sample support, stop fluid flow, and/or warm up the Peltier. Advantageously, this enables safe removal of a sample holder in a short period of time during an emergency (e.g., vacuum burp or an issue inside the TEM).

The power input to the heating element on the MEMS sample support can be monitored to determine how close the in-situ microscopy system is to thermal equilibrium and to estimate the amount of thermal drift in the system as components heat and cool via the thermoelectric device. In some embodiments, the power monitoring is performed while maintaining a fixed temperature at the sample through a closed-loop control of the heating element on the MEMS sample support. For example, and without limitation, a control system can reduce a dose to the sample by blocking and/or stopping emission of electrons to the sample until the in-situ microscopy system is near or at thermal equilibrium. Advantageously, this can reduce the dose applied to the sample when it may be moving too fast to image and can be used to alert the user that the system components are still cooling down. Additionally, monitoring the power into the heating element on the MEMS sample support can be used to determine when all parts of the system are back to ambient room temperature when warming up the system as there can be temperature gradients on the components linking the thermoelectric device to the MEMS sample support.

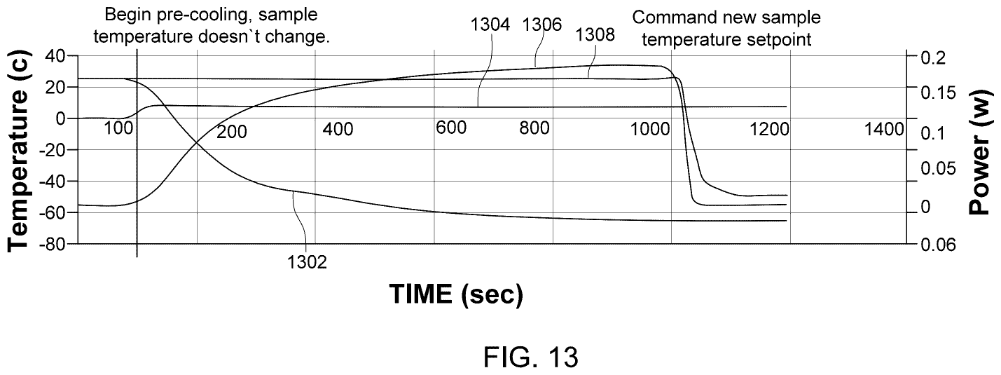

FIG. 13 depicts a plot of temperature of components of a heating and cooling TEM holder according to one embodiment of the present disclosure. Referring to FIG. 13, line 1302 represents the temperature measurement of the cold side RTD, line 1304 represents the Peltier voltage, line 1306 represents the sample temperature as measured by the sensing element on the E-chip, and line 1308 represents the power through the heating element on the E-chip. This plot represents a control option in which the Peltier is cooled with an open-loop command that cools off a significant portion of the sample holder, but the sample temperature is maintained at room temperature or any selected set point. The power in the E-chip increases to maintain that temperature while the parts around it get cold. The current through the E-chip is then either cut or reduced programmatically to controllably cool the sample. As can be seen from the plot shown in FIG. 13, in the specific case shown, the cooling of the sample occurred relatively quickly. The system disclosed herein allows for the current to be controlled to achieve any desired ramp rate.

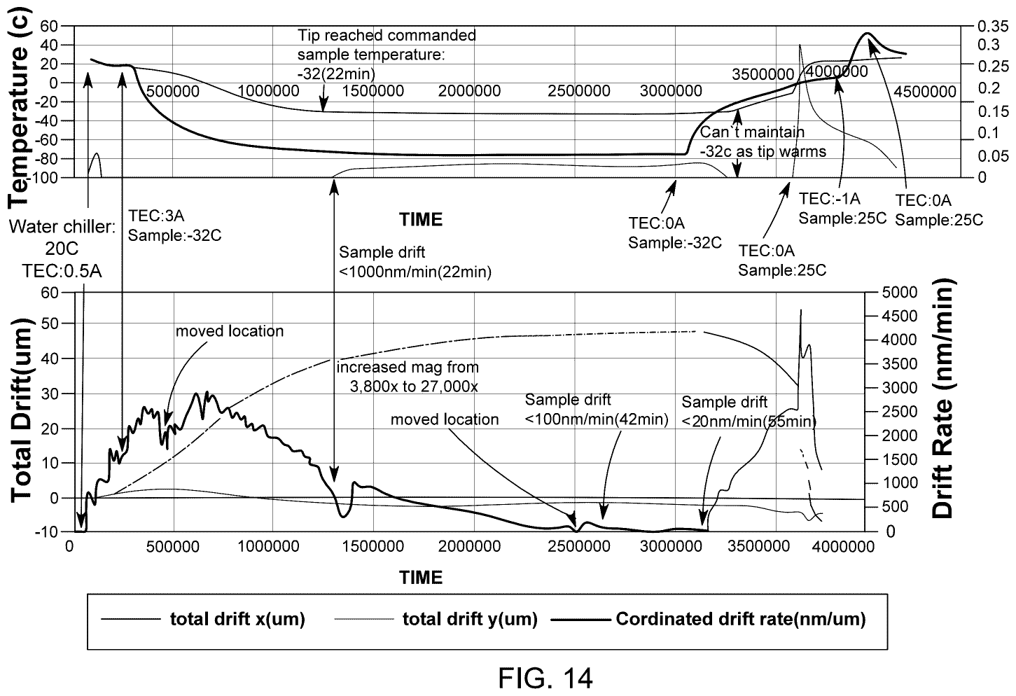

FIG. 14 depicts a graphical representation of the temperature and sample drift of a heating and cooling TEM holder according to one embodiment of the present disclosure.

The upper plot shown in FIG. 14 is a plot of temperature and power vs. time. The lines in the upper plot of FIG. 14 represent sample temperature, cold side RTD temperature, and sample power. The lower plot shown in FIG. 14 is a plot of sample drift vs. time. The lines in the lower plot of FIG. 14 represent total drift X, total drift Y, and coordinated drift rate. As can be seen from FIG. 14, there is a time delay and discrepancy between a cold side RTD measurement and the sample measurement due to the distance. FIG. 14 also shows that the system can be used to cool with the E-chip purely measuring the temperature vs. controlling a temperature. The drift magnitude is large but largely directional with the axis of the holder. As can be seen in FIG. 14, the closed-loop controller kicks in to maintain a temperature set point on the sample.

Then on the right side of the plot, the current is reversed through the Peltier which shows a process to warm parts of the holder with the larger power Peltier. It also shows that directional drift reverses and comes back close to the same position as the beginning of the experiment.

The hot side of the thermoelectric device may require active cooling as heat is pumped out of the system to cool down the MEMS sample support. This can be achieved by forced fluid, either air or liquid, and the temperature of the forced fluid can be manipulated as an additional control knob to reduce or raise the temperature of the entire system.

In some embodiments, the MEMS sample support may be used in part to contain liquid, gas, or humid air in a closed-cell configuration at the sample observation region. The components linking the thermoelectric device to the MEMS sample support are thermally conductive and thermally isolated from the microscope touch points.

The in-situ microscopy system includes a closed cell that is constructed so that a stiff part, or lid, is used to compress the conductive MEMS frame against a gasket to seal the liquid from the vacuum environment of the microscope column. The lid may be made with a material of high thermal conductivity and low coefficient of thermal expansion to improve heat transfer to the thermoelectric device. Alternatively, the lid may be replaced by a lid with less thermal conductivity if it is advantageous to reduce heat transfer between the MEMS sample support and the thermoelectric device for experiments requiring more heat from the heating element on the MEMS sample support than can be overcome by the thermoelectric device or when the thermoelectric device is not wanted for a particular experiment.

The lid may be fastened to or through materials of high thermal conductivity and lower coefficients of thermal expansion to improve conductivity to the thermoelectric device. For example, the lid is fastened using a plurality of screws positioned through the lid into other parts or screws going from the other components into or against the lid. Alternatively, the in-situ microscopy stem includes a cam feature, a captive clip, or parts that slide over the lid to compress the lid into the MEMS sample support.

In some embodiments, the closed cell may be constructed so that the liquid is also surrounded by material with high heat capacity to store heat from the heat source element on the MEMS sample support. These adjacent components storing heat from the MEMS sample support can be made with lower thermal conductivity so that the components react slower than the MEMS sample support as the sample support is heated and cooled by the TEC. With the TEC cold, and heat from the heat source element on the MEMS sample support stored in adjacent parts surrounding the liquid, the power to the heat source element on the MEMS sample support can be reduced. Advantageously, this will reduce the temperature of the MEMS sample support and the liquid near the MEMS sample support first, leaving the surrounding temperatures of the adjacent parts slightly higher and the fluid lines or fluid reservoirs connected to the cell slightly warmer. This enables the liquid closest to the sample to freeze before any fluid lines or reservoirs connected to the cell.

An electrochemistry “cell” can be formed using MEMS sample supports with various electrode materials in different configurations. The electrodes can be patterned on the surface of the MEMS sample support, with pre-defined areas exposed to the liquid contained in the cell and may be made from materials such as gold, platinum, carbon, and other materials common in electrochemical studies. The electrodes can be a platform for the user to add additional samples through common sample preparation techniques such as focused ion beam (FIB), drop casting and other methods. With these electrodes and heating elements both patterned on the MEMS sample support, electrochemical reactions can be studied at or above room temperature. Once coupled to a thermoelectric device, those electrochemical reactions can also be studied below room temperature.

In some embodiments, the closed cell can be constructed to include liquid surrounded by material with high heat capacity that can store heat from the heat source element on the MEMS sample support, temporarily keeping the surrounding temperatures slightly higher if the power to the heat source element is reduced. Advantageously, this enables the liquid closest to the sample to freeze before any fluid lines or reservoirs connected to the closed cell. In at least one aspect of the present disclosure, the control system is configured to automatically pause fluid flow to prevent pressure build-up in the closed cell. The sample can be thawed by warming the MEMS sample support and/or the Peltier device. In at least one aspect of the present disclosure, freezing of the in-situ microscopy system can be detected based on exothermic activity and an unexpected temperature increase. In response, the in-situ microscopy system can stop fluid flow.

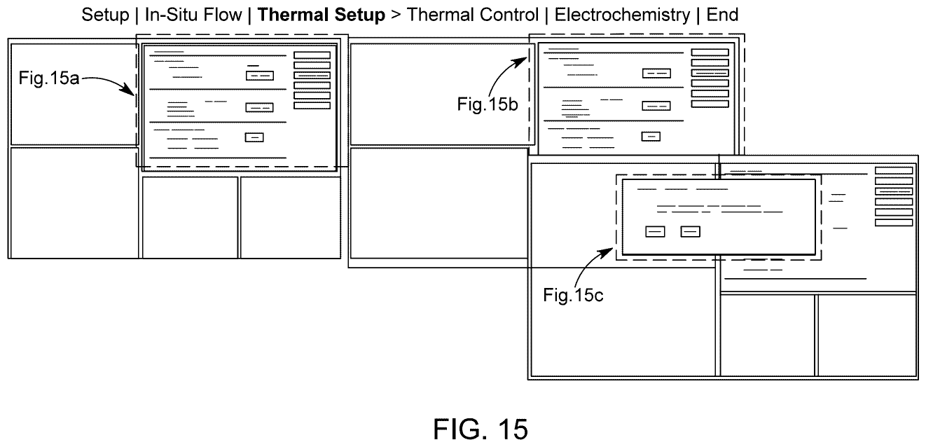

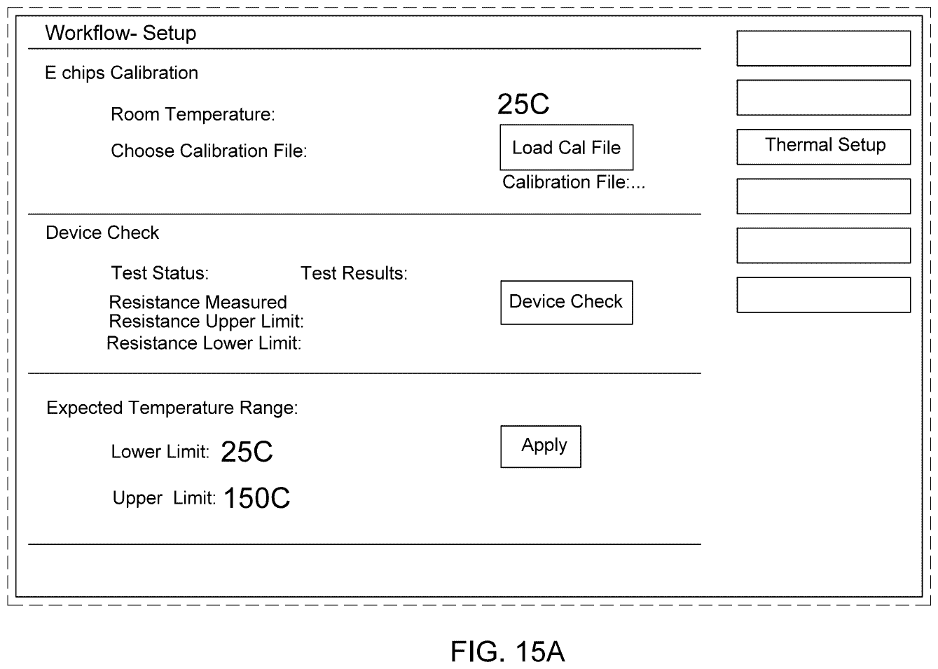

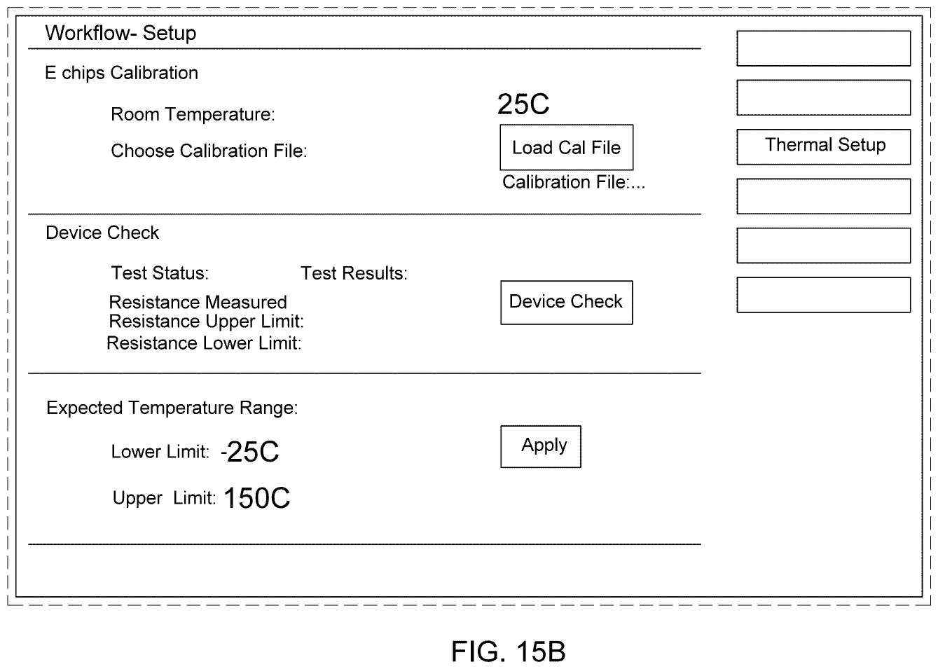

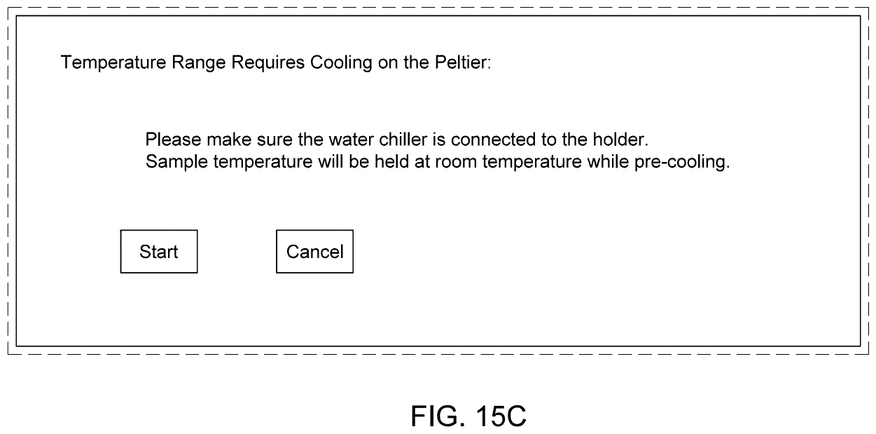

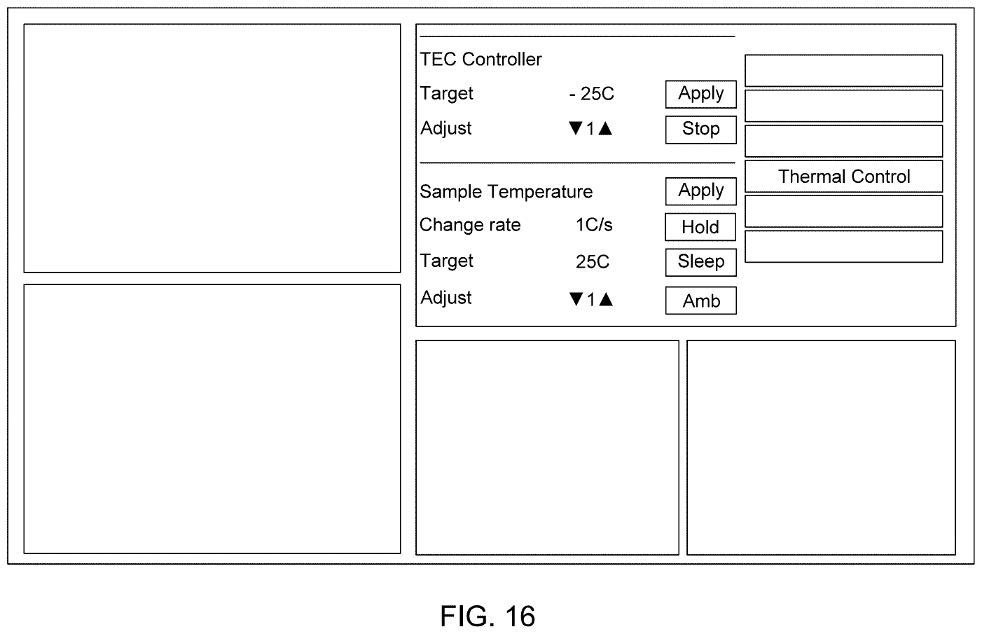

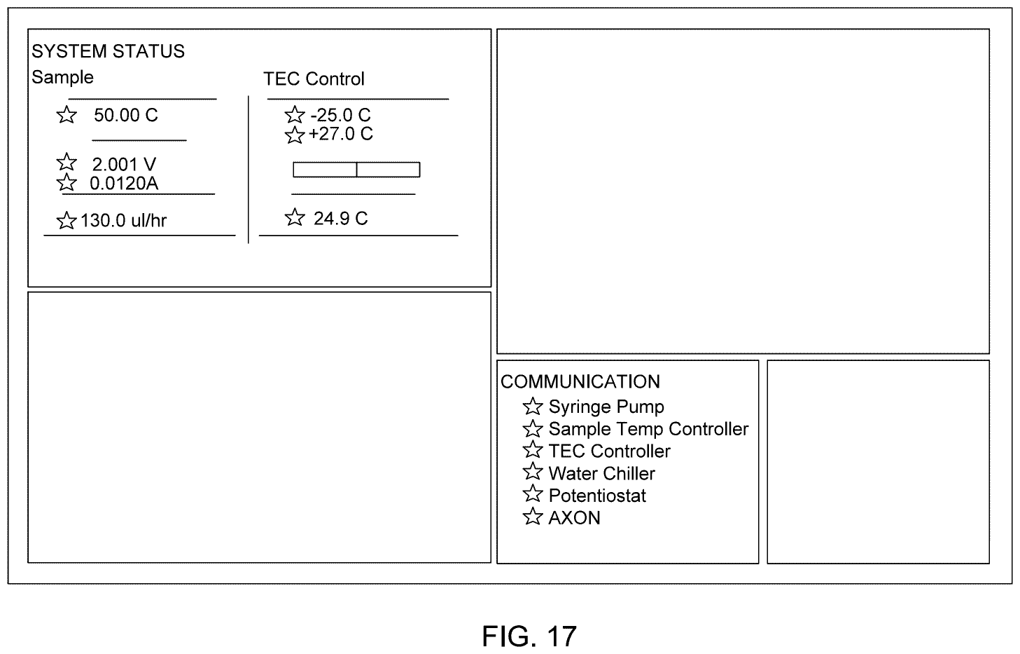

An example of a control process according to at least one embodiment of the present disclosure is illustrated in FIGS. 15-17. For example, and without limitation, the in-situ TEM system includes a software platform in network communication with a sample holder including a MEMS support device. The software platform is operable for thermal control of the in-situ TEM system. The software platform is operable for thermal setup including (1) room temperature; (2) calibration file; (3) device status; (4) expected temperature lower limit range; and (5) upper limit temperature range. The control system is further operable to generate an alert when a temperature range requires use of a Peltier or similar device. The alert includes a prompt to pre-cool a sample holder.

The control system is operable to receive user input via a remote device (e.g., computer, mobile device). The user input includes, but is not limited to, adjusting a temperature of the Peltier cooling system (e.g., water temperature setpoint of a water chiller) and adjusting the temperature of a sample.

The control system is operable to generate a system status. The system status includes a system temperature, electrochemistry voltage, electrochemistry ampere, and flow rate. The system status further indicates whether an experiment is active (e.g., thermal control on, potentiostat running, and/or liquid flow running). The control system further indicates a TEC control status including, but not limited to, a cold-side RTD, a hot-side RTD, a water chiller temperature, power status, pump status, and a time to reach thermal equilibrium. The control system further includes operating status (e.g., error) for a syringe pump, a sample temperature controller, a TEC controller, a water chiller, a potentiostat, and other similar components.

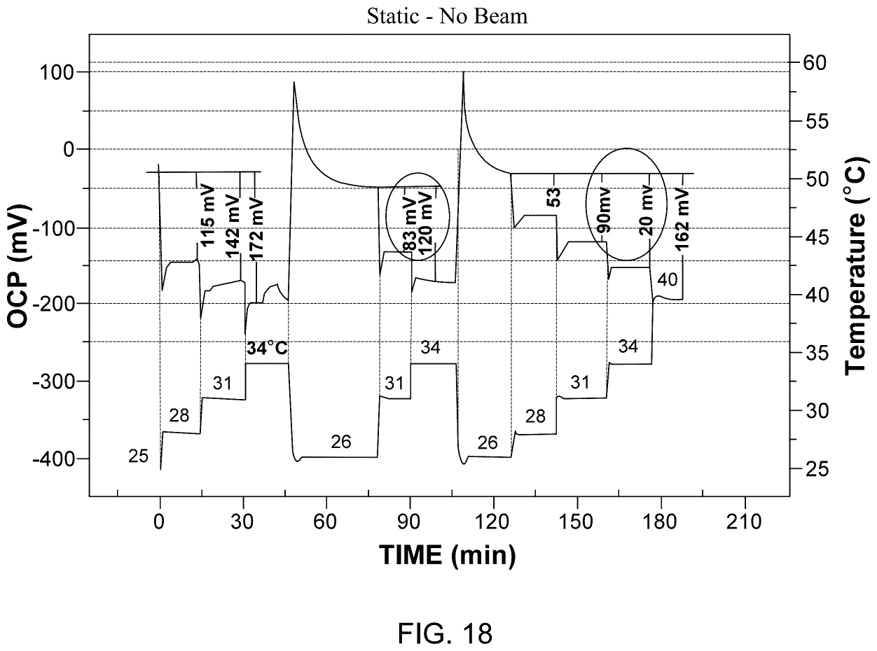

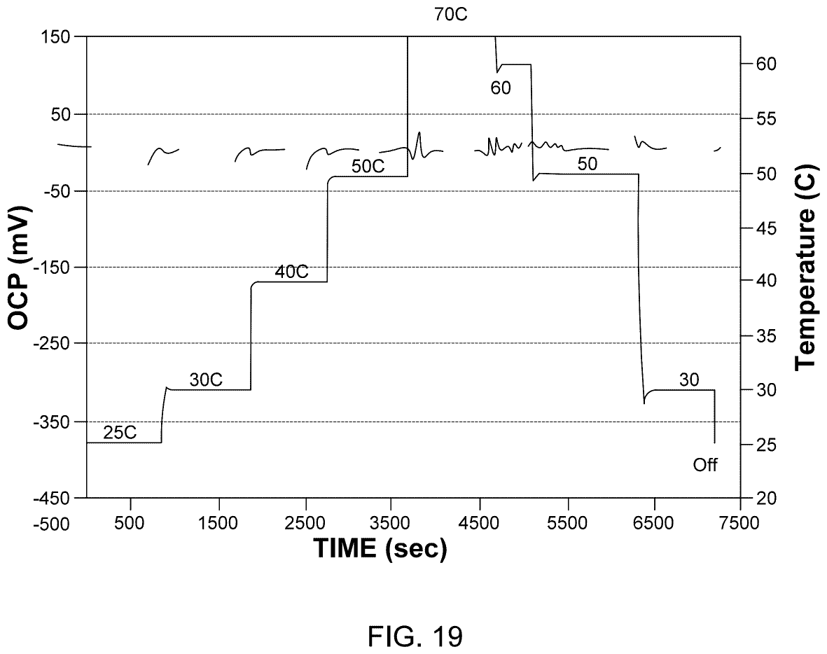

The in-situ microscopy system is further designed to minimize and reduce the effects of interference between a heating circuit and an electrochemistry circuit. This is accomplished, for example, by using a high-resistivity substrate, thick dielectric layers, low-leakage probes/probe array, and low-leakage connectors and cabling. As shown in FIGS. 18-19, the potential of an electrochemistry circuit changes when voltage is applied to the heating circuit.

FIG. 18 illustrates a graphical representation of interference between a heating circuit and an electrochemistry circuit.

Referring to FIG. 18, a cross-coupling may occur between thermal stimulus and electrochemistry measurements. As the temperature of the sample is increased, the current required to raise the temperature is coupled into the open-circuit potential measurements made on the wetted electrodes. Ideally, these circuits are completely isolated. In the example shown in FIG. 18, the open-circuit potential (as measured between the working electrode and the reference electrode on the chip, in the cell) is changing by >100 mV for very small changes in temperature (or very small changes in current through the heating element on the E-chip).

FIG. 19 illustrates a graphical representation of interference between a heating circuit and an electrochemistry circuit.

FIG. 19 shows reduction in cross-coupling achieved between thermal stimulus and electrochemistry measurements by utilizing a high resistivity substrate, thicker dielectric layers, a low leakage probe array and high-isolation connectors and cabling. These features provide higher resistance measurements between the thermal and electrochemistry circuits to achieve picoamp-scale leakage at 10V. Reducing leakage allows application of higher voltage/current on the thermal circuit to drive larger changes in temperature while minimizing the impact on the electrochemical measurements.

As will be appreciated by one skilled in the art, aspects of the technology described herein may be embodied as a system, method or computer program product. Accordingly, aspects of the technology may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the technology may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium (including, but not limited to, non-transitory computer readable storage media). A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the technology described herein may be written in any combination of one or more programming languages, including object oriented and/or procedural programming languages. Programming languages may include, but are not limited to: Ruby®, JavaScript®, Java®, Python®, PHP, C, C++, C #, Objective-C®, Go®, Scala®, Swift®, Kotlin®, OCaml®, or the like. The program code may execute entirely on the user's computer, partly on the user's computer, as a stand-alone software package, partly on the user's computer, and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the technology described herein refer to flowchart illustrations and/or block diagrams of methods, apparatus (systems) and computer program products according to various embodiments. It will be understood that each block of the flowchart illustrations and/or block diagrams, and combinations of blocks in the flowchart illustrations and/or block diagrams, can be implemented by computer program instructions.

These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the figures illustrate the architecture, functionality, and operation of possible implementations of systems, methods and computer program products according to various embodiments of the technology described herein. In this regard, each block in the flowchart or block diagrams may represent a module, segment, or portion of code, which comprises one or more executable instructions for implementing the specified logical function(s). It should also be noted, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The terminology used herein is for the purpose of describing particular embodiments only and is not intended to be limiting. As used herein, the singular forms “a,” “an” and “the” are intended to include the plural forms as well, unless the context clearly indicates otherwise. Thus, for example, reference to “a user” can include a plurality of such users, and so forth. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description provided herein has been presented for purposes of illustration and description, but is not intended to be exhaustive or limited to the specific form disclosed. Many modifications and variations will be apparent to those of ordinary skill in the art without departing from the scope and spirit of the disclosure. The embodiment was chosen and described in order to best explain the principles described herein and the practical application of those principles, and to enable others of ordinary skill in the art to understand the technology for various embodiments with various modifications as are suited to the particular use contemplated.

The descriptions of the various embodiments of the technology disclosed herein have been presented for purposes of illustration, but these descriptions are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. An in-situ electron microscopy system for controlling heating and cooling of a sample being observed during an experimental session, the system comprising:
a sample holder;
a micro-electro-mechanical system (MEMS) sample support comprising at least one heat source element, an insulating material, and a thermally conductive frame;
a heating and cooling system coupled to the sample holder and the sample support,
wherein the heating and cooling system comprises:
at least one thermoelectric device, wherein the at least one thermoelectric device includes a housing, a hot side, and a cold side;
a controller, wherein the controller comprises at least one hardware processor configured for:
controlling power of the at least one thermoelectric device and the MEMS sample support;
adjusting power of the at least one thermoelectric device and the MEMS sample support to reach a target temperature for the sample held by the sample holder being observed during the experimental session.

2. The in-situ electron microscopy system of claim 1, wherein the sample holder comprises a tip, a thermal break, a body portion, a cold finger, a housing, a plurality of cooling components, and a plurality of electrical connectors.

3. The in-situ electron microscopy system of claim 1, wherein the heating and cooling system further comprises at least one resistance temperature detector (RTD), wherein the at least one RTD is operable to monitor a temperature of the at least one thermoelectric device.

4. The in-situ electron microscopy system of claim 1, wherein the at least one thermoelectric device includes a Peltier device having a heat-sink.

5. The in-situ electron microscopy system of claim 4, wherein the at least one hardware processor is further configured for controlling current through the Peltier device, wherein the current through the Peltier device corresponds to a target temperature or target power for the sample.

6. The in-situ electron microscopy system of claim 5, wherein the at least one hardware processor is further configured for adjusting current through the Peltier device to minimize thermal drift or affect a speed of a cooling or heating process.

7. The in-situ electron microscopy system of claim 4, wherein heat generated from the Peltier device is directed to the MEMS sample support.

8. The in-situ electron microscopy system of claim 4, wherein the at least one heat source on the MEMS sample support is independently controlled via Joule heating.

9. The in-situ electron microscopy system of claim 8, wherein the MEMS sample support further includes at least one temperature sensing element, wherein the at least one temperature sensing element is operable to determine a temperature of the MEMS sample support.

10. The in-situ electron microscopy system of claim 1, wherein the sample holder is thermally coupled to the MEMS sample support.

11. The in-situ electron microscopy system of claim 1, wherein the at least one hardware processor is further configured for monitoring a temperature of the MEMS sample support.

12. The in-situ electron microscopy system of claim 1, wherein the at least one thermoelectric device includes a plurality of cooling components, wherein the cooling components are in contact with the sample holder or the thermoelectric device.

13. The in-situ electron microscopy system of claim 1, wherein the at least one hardware processor is further configured for:
determining a magnitude and a rate of thermal drift of the sample;
adjusting the power of the MEMS sample support or the power of the at least one thermoelectric device based on the magnitude of thermal drift or the rate of thermal drift.

14. A method for managing temperature of a sample in an in-situ microscopy environment, the method comprising:
heating a sample positioned in a sample holder to a target temperature via a micro-electro-mechanical system (MEMS) sample support, wherein the MEMS sample support includes at least one heat source element, an insulating material, and a thermally conductive frame;
determining, via at least one temperature sensing element, a temperature of the at least one heat source element and the sample;
adjusting, via at least one processor, a power of at least one thermoelectric device based on the temperature of the at least one heat source element and/or the sample, wherein the at least one thermoelectric device includes a housing, a heat generating side, and a heat dissipating side, wherein the at least one thermoelectric device is thermally coupled to the sample holder; and
determining, via the at least one processor, when the in-situ microscopy environment reaches thermal equilibrium.

15. The method of claim 14 further comprising determining, via the at least one processor, a magnitude and a rate of thermal drift of the sample; and adjusting the temperature of the MEMS sample support or the temperature of the at least one thermoelectric device based on the magnitude of thermal drift or the rate of thermal drift.

16. A temperature-controlling sample-support device for a micro-electro-mechanical (MEMS) system comprising:
a thermally conductive substrate with at least one dielectric layer and a heat source element;
wherein the thermally conductive substrate is thermally coupled to a thermoelectric device, wherein the thermoelectric device is operable to heat and cool the thermally conductive substrate.

17. The temperature-controlling sample-support device of claim 16, wherein the thermally conductive substrate has patterned electrodes capable of electrically biasing a sample at varying temperatures in an observation region of a sample holder.

18. The temperature-controlling sample-support device of claim 16, wherein the thermoelectric device is used to cool down the thermally conductive substrate, wherein the heat source element on the MEMS temperature-controlling sample-support device is configured to measure the temperature local to a sample.

19. The temperature-controlling sample-support device of claim 16, wherein the thermoelectric device is driven to specific temperatures or power at programmable rates by adjusting the current through the thermoelectric device, wherein the heat source element on the MEMS temperature-controlling sample-support device is driven to specific temperatures at programmable rates by adjusting the current through the heat source element.

20. The temperature-controlling sample-support device of claim 16, wherein the thermoelectric device is driven to a temperature just below a temperature of interest and the heat source element on the MEMS temperature-controlling sample-support device driven just above the temperature of interest and then the current adjusted through the heat source element on the MEMS temperature-controlling sample-support device as to cross through the temperature of interest with lower thermal drift and local sample temperature control.
